(19) United States
(12) Patent Application Publication
(10) Pub. No.: US 2024/0105740 A1
(43) Pub. Date: Mar. 28, 2024

(54) PHOTODIODE DEVICE WITH ENHANCED CHARACTERISTICS

(71) Applicant: AMS-OSRAM AG, Premstatten (AT)

(72) Inventors: Frederic Roger, GRAZ (AT); Gerald Meinhardt, GRAZ (AT); Ingrid Jonak-Auer, GRAZ (AT); Eugene G. Dierschke, DALLAS, TX (US)

(73) Assignee: ams-Osram AG, PREMSTÄTTEN (AT)

(21) Appl. No.: 18/256,286

(22) PCT Filed: Dec. 8, 2021
(86) PCT No.: PCT/EP2021/084801

§ 371 Date: Jun. 7, 2023

Related U.S. Application Data
(60) Provisional application No. 63/124,109, filed on Dec. 11, 2020.

(30) Foreign Application Priority Data
Feb. 3, 2021 (DE) 102021102497.8

(51) Int. Cl. H01L 27/146

(52) U.S. Cl. CPC H01L 27/14607; H01L 27/1462; H01L 27/14636; H01L 27/14643

(57) ABSTRACT

A photodiode device includes a semiconductor substrate with a main surface, the semiconductor substrate being of a first type of electric conductivity. The main surface includes at least one incidence area for electromagnetic radiation. A plurality of doped wells of a second type of electric conductivity are arranged at the main surface of the substrate, the second type of electric conductivity being opposite to the first type of electric conductivity. The doped wells and the substrate are electrically contactable. The doped wells are arranged along a perimeter of the at least one incidence area, such that a center region of the incidence area is free from the doped wells.

### CROSS-REFERENCE TO RELATED APPLICATIONS

The present application is a national stage entry from International Application No. PCT/EP2021/084801, filed on Dec. 8, 2021, published as International Publication No. WO 2022/122822 A1 on Jun. 16, 2022, and claims priority to German Patent Application 10 2021 102 497.8 filed Feb. 3, 2021, and U.S. Provisional Patent Application 63/124,109 filed Dec. 11, 2020, the disclosures of all of which are hereby incorporated by reference herein in their entireties.

### FIELD OF THE INVENTION

The invention relates to a photodiode device and an optoelectronic system.

### BACKGROUND OF THE INVENTION

There is an increasing demand for photodetectors with high sensitivity and spectral responsivity, the photodetectors therefore requiring low leakage currents. Especially for photodetectors fabricated according to standard CMOS technologies, the working principle is the conversion of optical intensity into a photocurrent or a voltage using photodiodes. Electromagnetic radiation enters the photodiode substrate and generates charge carriers which are collected by respective terminals.

Usually, photodiodes are formed by a pn-junction in the substrate, wherein an electric terminal connected to the n-type component forms the cathode and an electric terminal connected to the p-type component forms the anode. The pn-junction inherently has a junction capacitance which is why in conventional photodiode devices leakage currents can occur.

Moreover, the penetration depth of the electromagnetic radiation depends on its wavelength. Light of short wavelengths, in particular light in the blue wavelength range, penetrates the substrate only a few nanometers. The charge carriers generated there, but also charge carrier diffusing towards the surface of the substrate, can easily recombine and thus do not contribute to the photocurrent. Conventional photodiode devices therefore suffer from low responsivity, especially in the blue spectral range of wavelengths.

The photodiodes can be connected with a CMOS circuit by wafer-to-wafer bonding, by flip-chip assembly of semiconductor chips, or by monolithic integration of CMOS components and photodiodes in the same semiconductor device. Apart from being a very cost-effective solution, a monolithic integration provides the best interconnection between the photodiodes and the CMOS circuitry. However, semiconductor materials that are suitable for CMOS circuits may cause difficulties in integrating photodiodes with respect to leakage, capacitance, sensitivity, spectral responsivity, response time, and radiation hardness.

It is an objective to provide an improved concept for a photodiode device with enhanced characteristics, which overcomes the above mentioned drawbacks. It is further an objective to provide an electronic system comprising a photodiode device with enhanced characteristics.

This object is achieved with the photodiode device according to the independent claim. Embodiments derive from the dependent claims.

### SUMMARY OF THE INVENTION

In an embodiment a photodiode device comprises a semiconductor substrate with a main surface, the semiconductor substrate being of a first type of electric conductivity. The main surface comprises at least one incidence area for electromagnetic radiation. A plurality of doped wells of a second type of electric conductivity is arranged at the main surface of the substrate, the second type of electric conductivity being opposite to the first type of electric conductivity. The doped wells and the substrate are electrically contactable. The doped wells are arranged along a perimeter of the at least one incidence area, such that a center region of the incidence area is free from the doped wells.

The semiconductor substrate has a main plane of extension. The main surface of the semiconductor substrate runs parallel to the main plane of extension. The semiconductor substrate comprises, for example, silicon. The semiconductor substrate may have a base doping, in particular a base doping of the first type of electric conductivity. For example, the first type of electric conductivity is p-type and the second type of electric conductivity is n-type, or vice versa.

In a preferred embodiment the semiconductor substrate comprises a higher doped semiconductor body and a lower doped device layer, which is epitaxially grown on the semiconductor body. The main surface may be formed by the device layer. This means that in a transversal direction the device layer is arranged above the semiconductor body. The transversal direction runs perpendicular to the main plane of extension of the substrate.

The at least one incidence area is an area where electromagnetic radiation is incident. The incidence area may form a single photodetector. However, the photodiode device can also comprise more than one incidence area. In particular, a plurality of incidence areas is arranged at the main surface, such that an array of incidence areas is formed. In this case, each incidence area may form a pixel of the photodiode device. Each incidence area comprises a center region and a periphery. The periphery defines the perimeter of the incidence area.

The doped wells are arranged at the main surface of the substrate. In particular, the doped wells may be formed within the device layer. Each doped well has an extent in lateral directions, wherein lateral directions run parallel to the main plane of extension of the substrate. Each doped well also has an extent in the transversal directions. The doped wells comprise an upper surface, which is arranged at the main surface of the substrate. This means that the upper surface of each doped well is on a same level as the main surface and forms a part of the main surface. Each doped well reaches from the main surface of the substrate to a certain depth into the substrate. This can mean that each doped well is embedded in the device layer of the semiconductor substrate.

The doped wells are arranged at the periphery of the at least one incidence area. This means that in lateral directions each center region of the incidence area is surrounded by the doped wells. The doped wells can be distributed equally along the perimeter of the incidence area. On each lateral side of the incidence area there is at least one doped well. The center region of the incidence area is free from the doped wells.

The doped wells and the substrate can be contacted electrically. In case that the doped wells are n-type, an electric contact of the doped wells forms a cathode terminal. Accordingly, an electric contact of the substrate, which is p-type in this case, forms an anode terminal. As mentioned above, the type of electric conductivity of the doped wells and the substrate can be vice versa.

A contact region may be arranged on the upper surface of each doped well. The contact region has the same type of electric conductivity as the doped well, but its doping concentration is higher. The contact region enables the formation of an Ohmic contact to the respective doped well. Correspondingly, a further contact region may be arranged on the main surface of the substrate. The further contact region has the same type of electric conductivity as the substrate, but its doping concentration is higher. The further contact region enables the formation of an Ohmic contact to the substrate. Alternatively, the substrate may be electrically contacted from a rear side of the substrate.

At least some of the doped wells may be electrically connected in parallel with each other. The doped wells within one incidence area can be electrically connected with each other via a conductor track. This can mean, that each of the doped wells is electrically connected with the conductor track. In this way, the incidence area including the doped wells form a single photodetector or a single pixel within an array of pixels of the photodetector.

The photodiode device is provided to convert electromagnetic radiation into an electric signal. When photons of sufficient energy hit the incidence area of the photodiode device, charge carriers, i.e. electron-hole pairs, are generated. The charge carriers drift towards the respective electric terminals and lead to a photocurrent. The drift of the charge carriers takes place by diffusion. Therefore, the size of the incidence area in lateral directions may be such that it is equal as or less than a diffusion length of the charge carriers.

The doped wells form a pn-junctions with the substrate. As the doped wells are exclusively arranged at the periphery of the incidence area, the junction capacitance and the leakage of the photodiode device can be low since the center region that is surrounded be the doped wells can be free of pn-junctions. This is turn increases the spectral responsivity of the photodiode device. Moreover, lateral diffusion of charge carriers out of the incidence area is minimized due to the doped wells at the periphery.

The photodiode device can be monolithically integrated into a CMOS-integrated circuit. The monolithic integration offers huge advantages over a discrete solution consisting of a discrete photodiode array and a discrete ASIC, namely yield, costs and performance.

In some embodiments, the incidence area has a rectangular, in particular square shape in top-view, such that the doped wells form a frame surrounding the center region of the incidence area. The top-view refers to a view on the photodiode device from a side facing the main surface of the substrate. In lateral directions, the center region may be surrounded by a discrete number of doped wells. This means that the doped wells are separated from each other. In some embodiments, however, at least some of the doped wells are adjacent to each other, such that they form a fused doped well. As the incidence area has a rectangular shape in top-view, further incidence areas can be arranged next to it such that an array is formed.

In some embodiments, each side of the incidence area has a length, the length being between 40 μm and 120 μm. In further embodiments the length of each side of the incidence area is between 60 μm and 100 μm.

The electric terminals, in particular the cathode terminals contacting the doped wells, are arranged at the periphery of the incidence area. The side lengths of the incidence area should therefore be selected such that charge carriers can diffuse to the corresponding electric terminals. The side lengths can correspond to a diffusion length of the charge carriers. This ensures that a major part of the generated charge carriers contributes to the photocurrent before being lost through recombination processes in the substrate or at the main surface of the substrate.

In some embodiments, the center region accounts for at least 40% of the incidence area. In some further embodiments, the center region accounts for at least 60% or, alternatively, for at least 80% of the incidence area. As the center region is free from doped wells, there is hardly any pn-junction within the incidence area. Thus, the larger the center region, the smaller the junction capacity within the incidence area. The photodiode device therefore exhibits reduced leakage currents, which in turn increases the spectral responsivity.

In some embodiments, the center region of the incidence area comprises a doped surface region of the first type of electric conductivity.

The doped surface region is arranged at the main surface of the substrate. The doped surface region may cover the entire incidence area that is not covered by the doped wells. In other words, the doped surface region may also be arranged at the periphery of the incidence area and between the doped wells. The doped surface region is formed within the device layer and has a doping concentration that is higher than the doping concentration of the device layer. However, the doping concentration of the doped surface region may be lower than a doping concentration of a standard p+ implantation used for source/drain regions of metal-oxide-semiconductor field-effect transistors (MOSFET).

In lateral directions, the doped surface region may be adjacent to the doped wells. This means that the doped surface region may be in direct contact with the doped wells at the main surface of the substrate. In the transversal direction, the doped surface region extends less into the substrate than the doped wells. If the semiconductor substrate is p-type, the doped surface region is p-type as well, whereas the doped wells are n-type. The doped wells may have a doping concentration which is typical for so-called n-wells in a CMOS fabrication process. The junction capacitance between the doped wells and the doped region can be kept low due to the relative low doping concentrations.

The photodiode device avoids the usage of a field-oxide or of a shallow trench isolation at the main surface of the substrate by means of the doped surface region. In conventional devices, where a field-oxide is used, the speed of the photodiode is impaired by the Fermi-level pinning effect underneath field-oxide regions. This effect is mostly present in p-type semiconductors typically used in standard CMOS processes. By banding the conduction and valence band, respectively, charge carriers are accumulated underneath the field-oxide that translate to a slow turn-on behaviour. This slow response is most pronounced for low current levels. That means that after an excitation pulse the photocurrent remains at the level of the dark current level for several tens of milliseconds until the photodiode eventually produces the desired photocurrent. The same mechanism deteriorates the leading edge of a photocurrent pulse after illumination is turned on, causing decreased sensitivity of the photodetector for several integration periods of an analog-to-digital converter (ADC) readout circuitry.

By applying the doped surface region, which may be a very shallow, highly doped p-type implantation region, these issues are addressed and the response of the photodiode is increased. Furthermore, the doped surface region can provide good radiation tolerance of the device. For example, the doped surface region protects the underlying layers from damage caused by X-rays and prevents degradation of the photodiode device. Furthermore, minority carriers are repelled away from the main surface due to the doped surface region. Thus, the spectral responsivity of the photodiode device is increased and the leakage currents are decreased. The doped surface region can further be provided to establish a low Ohmic electrical contact to the substrate.

As the doping concentration of the doped surface region may be lower than a doping concentration of a standard p+ implantation used for source/drain regions of MOSFETs, p+ doping induced recombination, in particular Auger recombination, is prevented. Auger recombination is the more probable, the higher the doping concentration. This is in turn leads to a high responsivity, as the charge carriers can contribute to the photocurrent.

According to some implementations, there is a spacing between the doped wells and the doped surface region in lateral directions. This can mean that the doped surface region is not adjacent to the doped wells. In contrast, the doped wells and the surface region are separated by the lower doped device layer. By way of example, the spacing between the doped wells and the doped surface region is between 0.1 μm and 3 μm. The junction capacitance between the doped wells and the doped region can be kept low due to the spacing between those components. Therefore, the leakage currents are reduced and the spectral responsivity is enhanced.

In some embodiments, the photodiode device further comprises an epi-layer of the first type of electric conductivity arranged on the center region of the incidence area.

The epi-layer may be epitaxially grown on the main surface of the substrate. This means that the epi-layer has few crystal defects. The epi-layer can cover the entire incidence area that is not covered by the doped wells. This means that in the transversal direction a region above the doped wells is free from the epi-layer. In lateral directions the epi-layer may have a distance to the doped wells. However, the epi-layer may also be adjacent to the doped wells in lateral direction. That the epi-layer slightly overlaps the doped wells is likewise possible. The epi-layer may be arranged at regions on the main surface not covered by the doped surface region.

In the transversal direction the epi-layer can have a thickness of less than 100 nm. For example, the thickness of the epi-layer in the transversal direction is less than 50 nm or less than 10 nm.

The doping concentration of the epi-layer can be higher than the doping concentration of the device layer of the substrate. The epi-layer can be in-situ doped so that crystal damage caused by ion implantation is avoided. Compared to ion implant doping, this leads to reduced leakage currents and higher responsivity, in particular in the blue spectral range.

Furthermore, minority carriers are repelled away from the main surface due to the higher doping concentration of the epi-layer in comparison to the doping concentration of the device layer. Due to the higher doping the Fermi level is closer to the edge of the valence band, which increases the energy barrier for the minority charge carriers diffusing towards the main surface. Therefore, the photo-induced charge carriers are prevented from recombining at the main surface and can contribute to the photocurrent. The spectral responsivity of the photodiode device is therefore enhanced.

Additionally, the thickness of the epi-layer can be controlled very accurately so that the process variability is decreased and the reliability of the photodiode device is increased. The epi-layer can also be configured to protect the underlying layers. The epi-layer can be provided for radiation hardness of the photodiode device. For example, the epi-layer prevents degradation of the photodiode device if exposed to X-radiation.

In some embodiments, the photodiode device further comprises a dielectric surface passivation layer arranged on or above the center region of the incidence area. The dielectric surface passivation layer may be provided for repelling charge carriers. Alternatively or additionally, the dielectric surface passivation layer may be provided for use as anti-reflective coating.

The dielectric surface passivation layer can cover the entire incidence area. This means that the dielectric surface passivation layer can also cover the doped wells and the periphery of the incidence area. The dielectric surface passivation layer can be arranged on top of the doped surface region or on top of the epi-layer at least in places. In the transversal direction the dielectric surface passivation layer can have a thickness of less than 100 nm or less than 50 nm.

The dielectric surface passivation layer may comprise silicon nitride (SiN). For example, the dielectric surface passivation layer comprises at least one of stoichiometric SiN or non-stoichiometric silicon nitride (Si₃₊ₓN₄₋ₓ). With these materials positive space charges can be formed in the dielectric surface passivation layer. Alternatively, the dielectric surface passivation layer can comprise at least one of aluminum oxide (Al₂O₃) or hafnium oxide (HfO₂). With these materials negative space charges can be formed in the dielectric surface passivation layer.

In both ways, an electric field is established at the main surface of the substrate. Due to the electric field photo-induced minority charge carriers are repelled away from the interface, such that recombination processes are prevented.

Moreover, surface recombination velocities are decreased. Therefore, the photocurrent is increased, which enhances the spectral responsivity. Thus, the minority charge carriers can contribute to the photocurrent. The spectral responsivity of the photodiode device is therefore enhanced.

The dielectric surface passivation layer can further be an anti-reflective coating. Thus, by employing the dielectric surface passivation layer the reflection of electromagnetic radiation at the main surface can be decreased. Additionally, the thickness of the dielectric surface passivation layer can be controlled very accurately so that the process variability is decreased and the reliability of the photodiode device is increased.

In some embodiments the photodiode device further comprises an oxide film arranged on the center region of the incidence area between the main surface and the dielectric surface passivation layer. For example, the oxide film is a thin native oxide film. Alternatively, the oxide film is deposited on the incidence area, except on contact regions of the doped wells and of the substrate. The oxide film aims to avoid the formation of cobalt-silicon, also called silicide, in that areas. Silicide is a metallic layer which is unwanted in the optical area, i.e. the incidence area, because it reflects photons. After deposition, the thickness of the oxide film can be reduced. The oxide film saturates surface states at the main surface of the substrate, also called dangling bonds. Thus, the combination of the oxide film and the dielectric surface passivation layer improves the spectral responsivity.

According to some implementations, the dielectric surface passivation layer comprises positive space charges. As mentioned above, this can be achieved by using, for example, silicon nitride as material for the dielectric surface passivation layer. Positive space charges within the dielectric surface passivation layer cause an inversion layer at the main surface of a p-type substrate. This means that minority charge carrier, in this case electrons, are attracted by the positive space charges.

In some other implementations the dielectric surface passivation layer comprises negative space charges. As mentioned above, this can be achieved by using, for example, Al₂O₃ or HfO₂ as material for the dielectric surface passivation layer. Negative space charges within the dielectric surface passivation layer cause an accumulation layer at the main surface of a p-type substrate. This means that majority charge carriers, in this case holes, are attracted by the negative space charges.

Both accumulation layer and inversion layer are suitable to passivate the main surface of the substrate. This can mean that charge carriers cannot recombine at the main surface. For example, if an inversion layer is formed by an excess of electrons at the main surface, photo-induced electrons diffusing towards the main surface will not find holes to recombine because they are already saturated by the excess of electrons. Due to the surplus of electrons they will diffuse away from the main surface again. If an accumulation layer is formed by an excess of holes at the main surface, the conduction band is bending upwards, such that minority charge carriers would have to overcome a higher energy barrier. This is sometimes called electron rejection boundary condition. In other words, the electric field caused by the space charges within the dielectric surface passivation layer results in repelling of minority charge carriers away from the main surface or the interface, respectively. This leads to a high responsivity, as the charge carriers can contribute to the photocurrent. Moreover, the surface recombination velocities at the interface between the main surface of the substrate and the dielectric surface passivation layer are low, as the surface states are saturated. This in turn leads to low leakage currents.

In some embodiments both the epi-layer and the dielectric surface passivation layer are comprised by the photodiode device. The epi-layer and the dielectric surface passivation layer can be arranged on top of each other in the transversal direction. The dielectric surface passivation layer can be arranged on top of the epi-layer.

In some embodiments, the photodiode device further comprises an intermetal dielectric arranged on or above the main surface of the substrate. The intermetal dielectric may comprise silicon oxide. In places, where the epi-layer and/or the dielectric surface passivation layer is present, the intermetal dielectric may be arranged on said layers.

At least one conductor track is embedded in the intermetal dielectric and electrically connected to the doped wells. At least one further conductor track is embedded in the intermetal dielectric and electrically connected to the substrate. In a preferred embodiment, the electric connections are at the periphery of the incidence area. This means that also the substrate is contacted outside the center region of the incidence area.

The conductor track and the further conductor track may be formed by metal layers embedded in the intermetal dielectric. For example, the conductor track and the further conductor track comprise aluminum. Besides of the conductor track and the further conductor track, further metal layers may be arranged within the intermetal dielectric. The conductor track and the further conductor track may also be electrically connected to an optional CMOS circuitry placed aside the photodiode device and/or to electrical contacts for external contacting. The conductor track may be electrically connected to the doped wells by means of contact plugs. In particular, the contact plugs each are arranged on the respective contact regions of the doped wells. Accordingly, the further conductor track may be electrically connected to the substrate by means of further contact plugs. In particular, the further contact plugs are arranged on respective further contact regions. The contact plug and the further contact plug may comprise a metal, for example tungsten and/or aluminum.

A region in the intermetal dielectric covering the center region of the incidence area may be free from conductor tracks and/or further conductor tracks. This is because the center region of the incidence area is free from doped wells, which have to be electrically contacted. The spectral responsivity of the photodiode device is increased since incident electromagnetic radiation is not blocked by the conductor tracks and the further conductor tracks in the center region.

In some further embodiments, the photodiode device further comprises a metal layer embedded in the intermetal dielectric. The metal layer covers the doped wells. The metal layer may be the topmost metal layer within the intermetal dielectric. In top-view, the metal layer may frame the center region of the incidence area. In other words, the region in the intermetal dielectric covering the center region of the incidence area may be free from the metal layer. By means of the metal layer the center region of the incidence area is sharply defined, such that incident electromagnetic radiation can only reach the center region. The metal layer can be provided to protect the underlying doped wells from high-energy radiation.

In some further embodiments, the photodiode device further comprises an array of incidence areas as described above. This means that each feature mentioned in conjunction with the at least one incidence area is also disclosed for the incidence areas within the array. In particular, each incidence area comprises a respective center region and a respective perimeter, along which doped wells are arranged. Moreover, a doped surface region, an epi-layer and/or a dielectric surface passivation layer may be arranged on or above the main surface of each incidence area. Each incidence area forms a pixel of the photodiode device.

At least one trench is arranged in the substrate surrounding each incidence area in lateral directions. The trench surrounds the respective incidence area including the plurality of doped wells without dividing this area. This means that the trench completely surrounds the respective incidence area including the plurality of doped wells. The doped surface region, the epi-layer and/or the dielectric surface passivation layer can cover the entire incidence area surrounded by the trench, apart from the doped wells. In the transversal direction, the trench extends further into the substrate than the doped wells. In particular, the trench may extend from the main surface until within the semiconductor body. This means, the trench extends completely through the device layer. The trench can extend through a part of the semiconductor body. This means, the trench does not extend completely through the semiconductor body.

According to some implementations, the trench is at least partially filled with a doped semiconductor material or an electrically insulating material. A dopant, for example a p-type dopant, can be introduced into sidewalls of the trench. Subsequently, the trench can be filled with an electrically insulating material, for example SiO₂. Alternatively, the trench is completely filled with a doped semiconductor material of the first type of conductivity. The trench or a filling of the trench can be electrically connected to a terminal. For example, the trench or a filling of the trench is electrically connected with the further conductor tracks.

As an alternative to the trench, at least one guard ring is arranged in the substrate surrounding each incidence area in lateral directions. The guard ring does not divide or intersect respective incidence areas. The guard ring may comprise an optional boundary region and a core region. The boundary region has the same type of conductivity as the doped surface region, and the core region has the opposite type of conductivity. The boundary region and the core region of the guard ring are electrically contactable. In particular, a ground potential (GND) is applied on the guard ring.

The trench or the guard ring are provided to prevent crosstalk between neighboring incidence areas. This has the advantage that photo-generated charge carriers are prevented from diffusing away from the respective incidence area. Reduced crosstalk can be in particular achieved, if the trench extends further into the substrate than the doped wells. Additionally, the trench and the guard ring enables a higher spectral responsivity and a low leakage current of the photodiode device.

In some embodiments, the center region of the at least one incidence area is free from a pn-junction. As such, the junction capacitance and the leakage of the photodiode device is low. This is turn increases the spectral responsivity of the photodiode device.

However, it is also possible that the photodiode device further comprises at least one further doped well of the second type of electric conductivity at the main surface of the substrate, the at least one further doped well being arranged in the center region of the at least one incidence area. The at least one further doped well provides an additional cathode terminal. The additional cathode terminal can be reached by the charge carriers faster than the cathode terminals at the periphery of the incidence area. Charge carrier can therefore be collected more efficiently by the electric terminals.

According to some implementations, the semiconductor substrate comprises an image grade epi starting material. The image grade epi starting material is provided for high charge carrier lifetime.

The mean distance L (diffusion length), that charge carriers in a semiconductor material travel due to diffusion during their lifetime T is determined by the equation

L²=D·τ,

where D is the diffusion coefficient. The lifetime T is defined by recombination processes within the semiconductor material. The diffusion length is used for the qualitative characterization of semiconductor crystals. At a given temperature, it depends on the number of recombination centers and adhesion points. The image grade epi starting material comprises less crystal defects than a conventional semiconductor material. Thus, the diffusion length is increased. For example, τ can be in the range of 0.1 ms and L² can be greater than 1 mm². This ensures a high photodiode functionality.

Furthermore, an optoelectronic system is provided that comprises the photodiode device. This means that all features disclosed for the photodiode device are also disclosed for and applicable to the optoelectronic system and vice-versa.

The optoelectronic system is provided for detection of electromagnetic radiation. In particular, ambient light is to be detected. The optoelectronic system may require a high sensitive photodiode device, which therefore exhibits low leakage and high spectral responsivity.

According to some implementations, the electromagnetic radiation to be detected is in the infrared wavelength range, in particular in the near-infrared wavelength range. In addition or alternatively, the electromagnetic radiation to be detected is in the visible wavelength range. It is also possible, that the electromagnetic radiation to be detected is in a range overlapping at least two of the infrared, the near-infrared or in the visible wavelength range.

In some embodiments, respective incidence areas of the array of incidence areas are adjusted to a portion of the wavelength spectrum. For example, for adjusting the sensitivity to a certain portion of the spectrum of incident electromagnetic radiation an optical wavelength filter can be arranged between the incidence area and a source of the incident electromagnetic radiation.

However, that X-radiation is to be detected is likewise possible. For example, the optoelectronic system is a computed tomography (CT) system. The X-rays are detected via a scintillator that transforms the X-rays into electromagnetic radiation detectable by the photodiode device. For example, the scintillator transforms the X-rays into visible light, which is then detected with the help of an array of photodiode devices. The scintillator may be arranged above the main surface of the substrate or above the intermetal dielectric.

The optoelectronic system may further comprise (CMOS-) circuitry for reading out electrical signals from the photodiode device. For example, for readout purposes the electronic system comprises storage capacitors, memory elements, an analog-to-digital converter (ADC) or the like.

The circuitry may be integrated on the same semiconductor substrate as the photodiode device. As such, a monolithic integration of CMOS components and photodiodes in the same semiconductor substrate can be achieved. Such optoelectronic systems can be conveniently employed in smart phones, tablet computers, laptops, camera modules or CT-applications. Moreover, the optoelectronic system may be used in the wearable segment, or for metrology and spectrometry applications.

### BRIEF DESCRIPTION OF THE DRAWINGS

The following description of Figures may further illustrate and explain aspects of the improved concept. Components and parts of the sensor arrangement that are functionally identical or have an identical effect are denoted by identical reference symbols. Identical or effectively identical components and parts might be described only with respect to the Figures where they occur first. Their description is not necessarily repeated in successive Figures.

FIG. 1 shows a top-view of an embodiment of a photodiode device.

FIG. 2 shows a top-view of another embodiment of a photodiode device.

FIG. 3 shows a cross-section of another embodiment of a photodiode device.

FIG. 4 shows a cross-section of another embodiment of a photodiode device.

FIG. 5 shows a cross-section of another embodiment of a photodiode device.

FIG. 6 shows a cross-section of another embodiment of a photodiode device.

FIG. 7 shows another cross-section of the embodiment according to FIG. 3.

FIG. 8 shows a graph showing doping concentration profiles of an embodiment of a photodiode device.

FIG. 9 shows a schematic of an optoelectronic system comprising a photodiode device.

### DETAILED DESCRIPTION

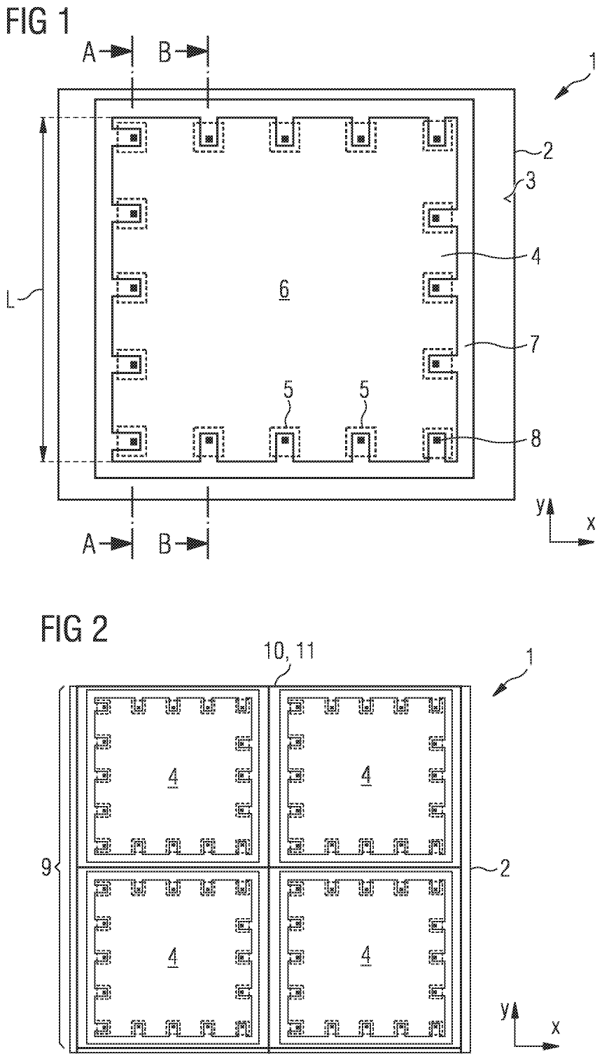

In FIG. 1 a top-view of an embodiment of a photodiode device 1 is shown. The photodiode device 1 comprises a semiconductor substrate 2 with a main surface 3. For example, the substrate 2 comprises silicon (Si). The substrate 2 has a main plane of extension. The main surface 3 extend in lateral directions x, y, wherein the lateral directions x, y run parallel to the main plane of extension of the substrate 2.

The semiconductor substrate 2 has of a first type of electric conductivity. The first type of electric conductivity is opposite to a second type of electric conductivity. For example, the first type of electric conductivity is p-type. Thus, the substrate 2 may be doped with boron (B).

The main surface 3 comprises at least one incidence area 4 for electromagnetic radiation. A plurality of doped wells 5 of the second type of electric conductivity is arranged at the main surface 3 of the substrate 2. For example, the second type of electric conductivity is n-type. The doped wells 5 are arranged along a perimeter of the at least one incidence area 4, such that a center region 6 of the incidence area 4 is free from the doped wells 5.

The doped wells 5 and the substrate 2 are electrically contactable. In FIG. 1 it is shown, that the doped wells 5 are electrically connected to a conductor track 7 via contact plugs 8. The electrical connection to the substrate 2 is omitted in FIG. 1.

It should be noted that some components, e.g. the doped wells 5 and the contact plugs 8, of the photodiode device can in fact be invisible from the viewer's perspective in the top-view according to FIG. 1. For the sake of clarity they are nevertheless shown in this Figure.

In the embodiment of FIG. 1 the incidence area 4 has a rectangular, in particular square shape in top-view. The doped wells 5 form a frame surrounding the center region 6 of the incidence area 4. The frame is formed by a discrete number of doped wells 5. In this example, each side of the incidence area 4 comprises five doped wells 5, wherein doped wells 5 at the corners of the incidence area 4 count for each of the adjacent sides. Therefore, the photodiode device 1 comprises sixteen doped wells 5 in total, which are distributed equally along the perimeter of the incidence area 4. However, the number of doped wells 5 as well as their distribution is merely exemplary.

Each side of the incidence area 4 has a length L. The length L can be defined by a metal layer surrounding the incidence area 4 in lateral directions x, y. The metal layer blocks incident electromagnetic radiation, such that electromagnetic radiation can enter the photodiode device 1 only at the incidence area 4. In the example of FIG. 1 the conductor track 7 defines the incidence area 4, as it comprises a portion surrounding said area in lateral directions x, y. Branches of the conductor track 7 extending towards the center region 6 of the incidence area 4 are electrically connected to the doped wells 5. For example, the length L is between 40 μm and 120 μm. Alternatively, the length L is between 60 μm and 100 μm.

The center region 6 takes up a substantial part of the incidence area 4. This can mean that the periphery of the incidence area 4 including the doped wells 5 takes up only an insignificant part of the incidence area 4. For example, the center region 6 accounts for at least 40% of the incidence area. Alternatively, it accounts for at least 60% or at least 80% of the incidence area 4.

The larger the center region 6, the more electromagnetic radiation can be detected by the photodiode device 1. Moreover, as the doped wells 5 are exclusively arranged at the periphery of the incidence area 4, the center region can be free from a pn-junction. This in turn reduces the junction capacitance and therefore also the leakage of the photodiode device 1. Besides, no metal layers are located above the center region 6, since there is no doped well 5 to be contacted in that region. Therefore, electromagnetic radiation is not blocked at the center region 6, such that it can reach the incidence area 4 mainly unblocked.

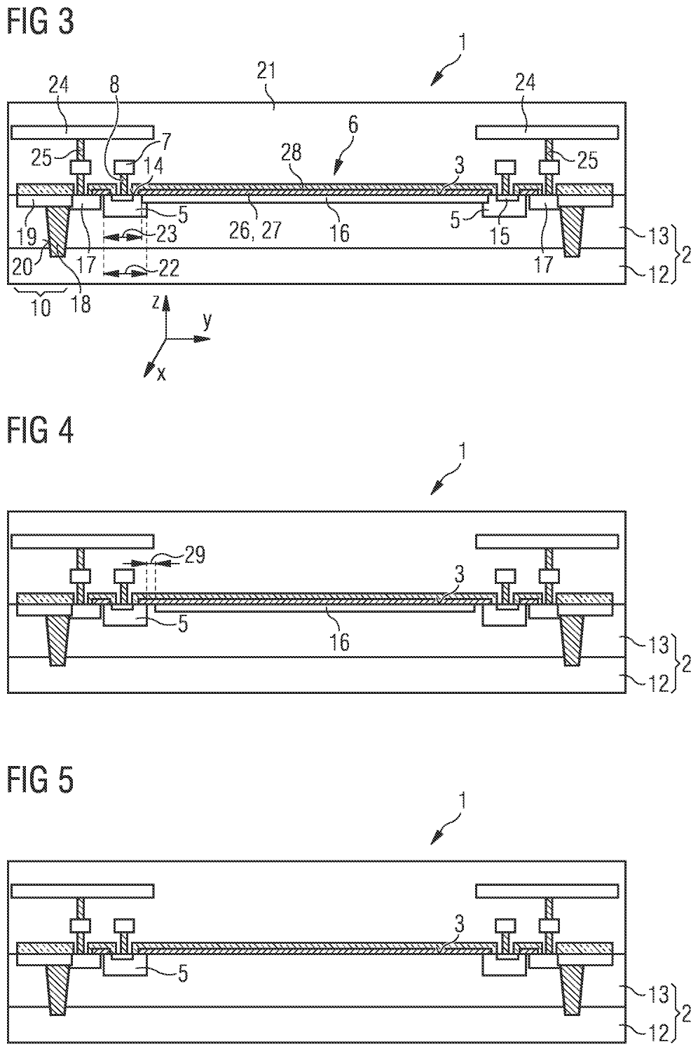

FIG. 1 further indicates two cross-sections along lines A-A and B-B. These cross-sections are shown in FIGS. 3 to 7, which are further described below.

FIG. 2 shows a top-view of another embodiment of the photodiode device 1. The photodiode device 1 according to FIG. 2 comprises an array 9 of incidence areas 4. The incidence areas 4 can be designed as shown in FIG. 1, which is why no further explanations are given in this respect. In this example, the array 9 comprises four incidence areas 4 arranged in a 2×2 matrix. However, the number of incidence areas 4 is merely exemplary. Further incidence areas 4 can be arranged next to each other such that a larger array 9 is formed.

The array 9 can be provided to generate a digital image with a sufficient resolution. Alternatively or additionally, each incidence area 4 within the array 9 can be provided to detect electromagnetic radiation of a particular wavelength range. For example, the incidence areas 4 can be arranged according to a Bayer pattern, such that two incidence areas 4 are provided to detect light in the green wavelength domain, one incidence area 4 is provided to detect light in the red wavelength domain and one incidence area 4 is provided to detect light in the blue wavelength domain. For example, for adjusting the sensitivity to a certain portion of the spectrum of incident electromagnetic radiation an optical wavelength filter (not shown) can be arranged between the respective incidence area 4 and a source of the incident electromagnetic radiation.

A trench 10 or a guard ring 11 is arranged in the substrate 2 surrounding each incidence area 4 in lateral directions x, y. The trench 10 or the guard ring 11 are provided to prevent crosstalk between neighboring incidence areas 4. The trench and the guard ring 11, respectively, are described in more detail below in context of the following Figures.

In FIG. 3 a cross-section through an embodiment of the photodiode device 1 is shown. That cross-section can correlate with the cross-section along the line B-B as indicated in FIG. 1. It is shown that the substrate 2 comprises a highly doped semiconductor body 12 and a lower doped device layer 13. The device layer 13 is arranged in a transversal direction z on top of the semiconductor body 12, wherein the transversal direction z is perpendicular to the main plane of extension of the substrate 2. The main surface 3 is thus formed by the device layer 13.

The doped wells 5 are arranged at the main surface 3 of the substrate 2. A first doped well 5 is arranged at a first side of the incidence area 4 and a second doped well 5 is arranged at a second side of the incidence area 4 opposite to the first side. The doped wells 5 are arranged at the periphery of the incidence area 4, such that the center region 6 in between is free from the doped wells 5.

The doped wells 5 have an extent in lateral directions x, y. For example, a lateral extent 22, 23 of the doped wells 5 is in the range of few micrometer. Furthermore, the doped wells extends in the transversal direction z. This means that the doped wells 5 reach from the main surface 3 into the substrate 2. The lateral extent 23 of the doped wells 5 at the main surface 3 may be different from their lateral extent 22 in deeper regions of the substrate 2. For example and as shown in FIG. 3, the doped wells 5 can be narrower at the main surface 3. The doped wells 5 comprise an upper surface 14. The upper surface 14 is formed by the main surface 3 of the substrate 2.

The doped wells 5 further comprise respective contact regions 15 placed at the upper surface 14 of each doped well 5. The contact region 15 has the same type of electric conductivity as the doped well 5, but comprises a higher doping concentration, so that an Ohmic contact can be established. In lateral direction x, y the contact region 15 may be placed in the center of the doped well 5.

The center region 6 of the incidence area 4 comprises a doped surface region 16 of the first type of electric conductivity. The doped surface region 16 is arranged at the main surface 3. The doped surface region 16 is adjacent to the doped wells 5. This means that the doped surface region 16 is in direct contact with the doped wells 5. The doped surface region 16 is doped for the first type of electric conductivity. The doped surface region 16 has a doping concentration that is higher than the doping concentration of the substrate 2 and in particular higher than the doping concentration of the device layer 13. In the transversal direction z, the doped surface region 16 is shallower than the doped wells 5. This means that the doped wells 5 reach deeper into the substrate 2.

FIG. 3 further shows a further contact regions 17 of the substrate 2. The further contact regions 17 are placed at the main surface 3. The further contact regions 17 have the same type of electric conductivity as the substrate 2, but have a higher doping concentration, so that an Ohmic contact can be established. Moreover, the further contact regions 17 can have a higher doping concentration than the doped surface region 16. In lateral direction x, y the contact regions 17 may be placed at the periphery of the incidence area. In the example of FIG. 3, the further contact regions 17 are further away from the center region 6 than doped wells 5.

Furthermore, FIG. 3 shows the trench 10, which surrounds the incidence area 4 in lateral directions x, y. The trench 10 comprises a deep trench portion 18. Besides, it may comprise a shallow trench isolation 19 at the main surface 3. The shallow trench isolation 19 is arranged between the main surface 3 and the deep trench portion 18. The shallow trench isolation 19 may also be omitted. The deep trench portion 18 may extend into the substrate 2 from the main surface 3 or from the shallow trench isolation 19. The trench 10 extends from the main surface 3 further into the substrate 2 than the doped wells 5. The trench 10 completely penetrates the device layer 13. The deep trench portion 18 stops in the semiconductor body 12. As shown in FIG. 3, the deep trench portion 18 tapers off towards the semiconductor body 12.

The trench 10 may comprise an insulating material, for example silicon oxide (SiO₂). However, a dopant, for example a p-type dopant, can be introduced into sidewalls 20 of the trench 10. As such, the sidewalls 20 of the trench 10 can be connected to an electric terminal via the further contact region 17. It is also possible that the trench 10 is completely filled with a doped semiconductor material. Thus, the trench 10 or the filling of the trench 10 can be electrically connected to a terminal.

The trench 10 prevents crosstalk between neighboring incidence areas 4, as photo-induced charge carriers cannot diffuse away. If the sidewall 20 is doped or if the filling of the trench 10 is a doped semiconductor material, minority charge carriers are repelled from the trench 10 because of the doping gradient. Thus, these charge carriers can contribute to the photocurrent.

The embodiment shown in FIG. 3 also comprises an intermetal dielectric 21 arranged on or above the main surface 3. The intermetal dielectric 21 may comprise silicon oxide (SiO₂), for example. Within the intermetal dielectric 21 the conductor track 7 and the contact plug 8 are arranged for contacting the doped wells 5. The conductor track 7 is embedded in the intermetal dielectric 21 and electrically connected to the doped wells 5 via the contact plugs 8. The conductor track 7 and the contact plugs 8 may comprise a metal. For example, the conductor track 7 comprises aluminum (Al). The contact plugs 8 can comprise tungsten (W) and/or aluminum.

Furthermore, FIG. 3 shows that a further conductor track 24 is embedded in the intermetal dielectric 21 and electrically connected to the substrate 2 via further contact plugs 25 and the further contact regions 17. The further conductor track 24 and the further contact plugs 25 may comprise a metal. For example, the further conductor track 24 comprises aluminum. The further contact plugs 25 comprise tungsten and/or aluminum. As shown on FIG. 3, the conductor track 7 and the further conductor track 24 are formed by different metallization levels. A region in the intermetal dielectric 21 covering the center region 6 of the incidence area 4 is free from conductor tracks 7 and/or further conductor tracks 24. The further conductor track 24 is arranged such that it covers the doped wells 5.

The embodiment shown in FIG. 3 also comprises an additional layer 26, 27 arranged on the center region 6 of the incidence area 4. For example, the additional layer is an epi-layer 26. The epi-layer 26 may be epitaxially grown on the semiconductor substrate 2. Therefore, the epi-layer 26 may also comprise silicon. The epi-layer 26 is doped for the first type of electric conductivity. Its doping concentration is higher than the doping concentration of the device layer 13, but lower than the doping concentration of the further contact region 17. The epi-layer 26 can cover the entire main surface 3 that is not covered by the doped wells 5 and the contact region 17. However, the epi-layer 26 can also be arranged on top of the further contact region 17 in places and/or on the upper surface 14 of the doped wells 5 in places.

Alternatively, the additional layer is an oxide film 27. For example, the oxide film 27 is a thin native oxide film 27. The oxide film 27 can also be deposited on the incidence area 4, except on contact regions 15 of the doped wells 5 and on further contact regions 17 of the substrate 2. The oxide film 27 aims to avoid the formation of silicide.

On top of the epi-layer 26 or the oxide film 27, respectively, a dielectric surface passivation layer 28 can be arranged, as shown in FIG. 3. This means that the epi-layer 26 or the oxide film 27 is arranged between the main surface 3 and the dielectric surface passivation layer 28. However, it is also possible that the dielectric surface passivation layer 28 is directly arranged on the main surface 3 without the epi-layer 26 or the oxide film 27 in between.

The dielectric surface passivation layer 28 covers the entire incidence area 4 including the upper surface 14 of the doped wells 5. That the dielectric surface passivation layer 28 only covers the center region 6 of the incidence area 4 is likewise possible. The dielectric surface passivation layer 28 is provided for repelling charge carriers and/or for use as anti-reflective coating.

The dielectric surface passivation layer 28 may comprise silicon nitride (SiN) or non-stoichiometric silicon nitride (Si₃₊ₓN₄₋ₓ). With these materials, the dielectric surface passivation layer 28 can comprise positive space charges. Thus an electric field is generated at the main surface 3 of the substrate 2 repelling charge carrier away from the interface.

The dielectric surface passivation layer 28 can also comprise at least one of aluminum oxide (Al₂O₃) and hafnium oxide (HfO₂). With these materials negative space charges can be formed in the dielectric surface passivation layer 28, also leading to an electric field at the main surface 3.

In FIG. 4 a similar embodiment of the photodiode device 1 as in FIG. 3 is shown. Here, there is a spacing 29 between the doped wells 5 and the doped surface region 16. This means that at the main surface 3 the doped wells 5 are spaced from the doped surface region 16 by the device layer 13. By means of the non-zero spacing 29 the junction capacitance between the doped wells 5 and the doped surface region 16 can be reduced.

In the embodiment of FIG. 5 there is no doped surface region 16 at all. This means that the doped surface region 16 can be omitted. Alternatively or in addition, the epi-layer 26 may be omitted. Alternatively or in addition, the oxide-film 27 may be omitted. Alternatively or in addition, the dielectric surface passivation layer 28 may be omitted.

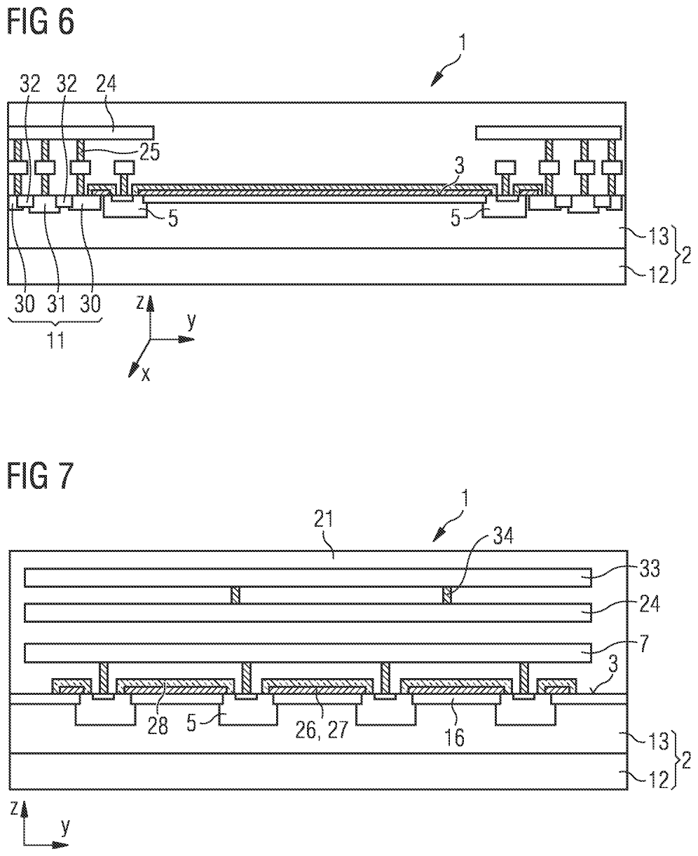

FIG. 6 shows another embodiment of the photodiode device 1 similar to the embodiment of FIG. 3. The only difference to the embodiment of FIG. 3 is that the trench 10 is replaced by the guard ring 11. The guard ring 11 comprises a boundary region 30 and a core region 31 arranged at the main surface 3. The boundary region 30 surrounds the core region 31 in lateral directions x, y. The boundary region 30 has the same type of conductivity as the substrate 2 and serves as contact region for the substrate 2. The core region 31 has the opposite type of conductivity. The boundary region 30 and the core region 31 of the guard ring 11 are electrically contactable. In particular, a ground potential (GND) is applied to the guard ring 11 by means of the further conductor track 24 and a plurality of further contact plugs 25. The boundary region 30 and the core region 31 may be separated by a further shallow trench isolation 32 placed at the main surface 3.

In FIG. 7 a cross-section through an embodiment of the photodiode device 1 is shown which can correlate with a cross-section along the line A-A indicated in FIG. 1. It shows a cut through the periphery of the incidence area 4.

It is illustrated that the doped surface region 16, the dielectric surface passivation layer 28 and the epi-layer 26 or the oxide film 27, respectively, can be arranged between the doped wells 5 at the periphery of the incidence area 4. Apart from the conductor track 7 electrically connecting the doped wells 5 and the further conductor track 24 electrically connecting the substrate 2 (further contact region 17 is not shown), an additional metal layer 33 is shown, which is embedded in the intermetal dielectric 21, too. The metal layer 33 is electrically connected to the further conductor track 24 via additional contact plugs 34. The metal layer 33 covers the doped wells 5. The metal layer 33 may be the topmost metal layer within the intermetal dielectric 21.

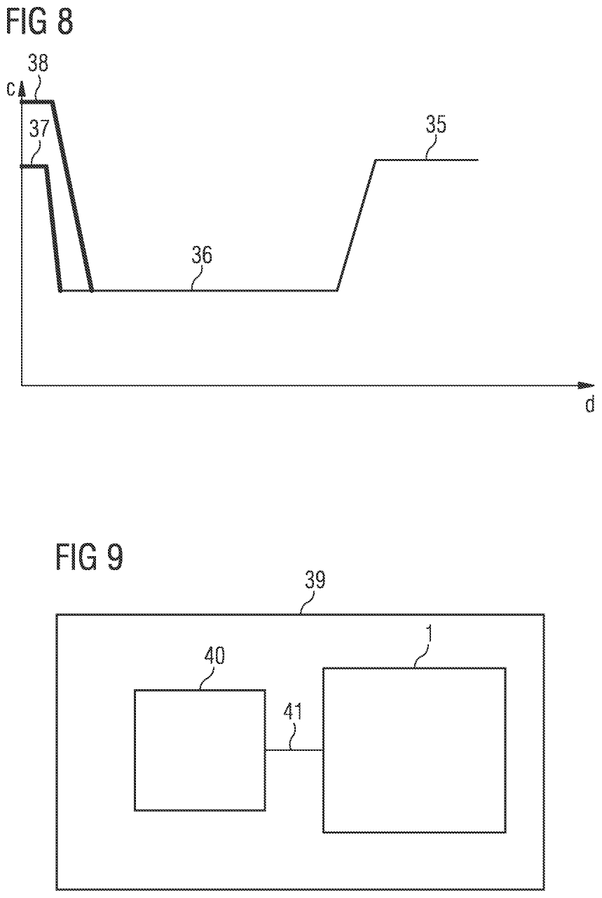

In FIG. 8 a graph illustrating doping concentration profiles of an embodiment of a photodiode device 1 is shown. The doping concentration c is shown as function of the depth d at various regions of the first type of electric conductivity within the substrate 2. The scaling of both axes c, d is arbitrary.

The doping concentration c comprises a first plateau 35 in deeper regions of the substrate 2 corresponding to the semiconductor body 12. With reducing the depth d, the doping concentration falls to a second plateau 36, corresponding to the doping concentration c of the device layer 13. Towards the main surface 3 the doping concentration raises and reaches a third plateau 37 at some places of the main surface 3. The third plateau 37 corresponds to the doping concentration c of the doped surface region 16. At other places of the main surface 3, namely at the further contact regions 17 of the substrate 2, the doping concentration reaches a fourth plateau 38, which is higher than the first plateau 35, the second plateau 36 and the third plateau 37. The doping concentration c of the further contact regions 17 is typical for drain and source regions of a p-type MOSFET.

FIG. 9 shows a schematic of an optoelectronic system 39 comprising the photodiode device 1. The optoelectronic system 39 further comprises circuitry 40 for reading out electrical signals from the photodiode device 1. For example, the circuitry 40 may include storage capacitors, memory elements, an analog-to-digital converter (ADC) or the like. The circuitry 40 is electrically connected to the photodiode device 1 by means of electric interconnection 41. The optoelectronic system 39 can be, for example, a camera system or an electromagnetic radiation sensor, especially for ambient light. The optoelectronic system 39 can be used for applications in the automotive, the industrial, the scientific and the medical field. Moreover, it can also be employed in consumer electronics.

The embodiments of the photodiode device disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1. A photodiode device, comprising:
a semiconductor substrate with a main surface, the semiconductor substrate being of a first type of electric conductivity, wherein the main surface comprises an incidence area for electromagnetic radiation,
a plurality of doped wells of a second type of electric conductivity at the main surface of the substrate, the second type of electric conductivity being opposite to the first type of electric conductivity, wherein
the doped wells and the substrate are electrically contactable, and wherein at least some of the doped wells being electrically connected with each other in parallel, and wherein
the incidence area forms a pixel within an array of pixels of the photodiode device and the doped wells are arranged along a perimeter of the incidence area, such that a center region of the incidence area is free from the doped wells.

2. The photodiode device according to claim 1, wherein the incidence area has a rectangular, in particular square shape in top-view, such that the doped wells form a frame surrounding the center region of the incidence area.

3. The photodiode device according to claim 1, wherein each side of the incidence area has a length, the length being between 40 μm and 120 μm or between 60 μm and 100 μm.

4. The photodiode device according to claim 1, wherein the center region accounts for at least 40%, at least 60% or at least 80% of the incidence area.

5. The photodiode device according to claim 1, wherein the center region of the incidence area comprises a doped surface region of the first type of electric conductivity.

6. The photodiode device according to claim 5, wherein in lateral directions, which run parallel to a main plane of extension of the substrate, there is a spacing between the doped wells and the doped surface region.

7. The photodiode device according to claim 1, further comprising an epi-layer of the first type of electric conductivity arranged on the center region of the incidence area.

8. The photodiode device according to claim 1, further comprising a dielectric surface passivation layer arranged on or above the center region of the incidence area, wherein the dielectric surface passivation layer is provided for repelling charge carriers and/or for use as anti-reflective coating.

9. The photodiode device according to claim 8, further comprising an oxide film arranged on the center region of the incidence area between the main surface and the dielectric surface passivation layer-484.

10. The photodiode device according to claim 8, wherein the dielectric surface passivation layer comprises positive space charges or negative space charges.

11. The photodiode device according to claim 1, further comprising
an intermetal dielectric arranged on or above the main surface of the substrate,
at least one conductor track embedded in the intermetal dielectric and electrically connected to the doped wells, and
at least one further conductor track embedded in the intermetal dielectric and electrically connected to the substrate, wherein
a region in the intermetal dielectric covering the center region of the incidence area is free from conductor tracks and/or further conductor tracks.

12. The photodiode device according to claim 11, further comprising a metal layer embedded in the intermetal dielectric, such that the metal layer covers the doped wells.

13. The photodiode device according to claim 1, further comprising an array of incidence areas as described in any of the preceding claims, wherein at least one trench or at least one guard ring is arranged in the substrate surrounding each incidence area in lateral directions, the trench or the guard ring being provided to prevent crosstalk between neighboring incidence areas.

14. The photodiode device according to claim 1, wherein the center region of the incidence area is free from a pn-junction.

15. The photodiode device according to claim 1, wherein the semiconductor substrate comprises an image grade epi starting material for high charge carrier lifetime.

16. An optoelectronic system comprising the photodiode device according to claim 1, wherein the optoelectronic system is provided for detection of electromagnetic radiation, in particular ambient light detection.

17. A photodiode device, comprising:
a semiconductor substrate with a main surface, the semiconductor substrate being of a first type of electric conductivity, wherein the main surface comprises an incidence area for electromagnetic radiation,
a plurality of doped wells of a second type of electric conductivity at the main surface of the substrate, the second type of electric conductivity being opposite to the first type of electric conductivity,
wherein the doped wells and the substrate are electrically contactable,
wherein the doped wells are arranged along a perimeter of the incidence area, such that a center region of the incidence area is free from the doped wells, and
wherein the photodiode device further comprises an epi-layer of the first type of electric conductivity arranged on the center region of the incidence area.
